(19) United States
(12) Patent Application Publication
(10) Pub. No.: US 2014/0131710 A1
(43) Pub. Date: May 15, 2014

(54) STRUCTURES AND TECHNIQUES FOR ELECTRO-STATIC DISCHARGE (ESD) PROTECTION USING RING STRUCTURED DIODES

(71) Applicant: Shine C. Chung, San Jose, CA (US)

(72) Inventor: Shine C. Chung, San Jose, CA (US)

(21) Appl. No.: 13/678,539

(22) Filed: Nov. 15, 2012

(51) Int. Cl. H01L 29/861; H01L 29/04; H01L 29/66

(52) U.S. Cl. CPC H01L 29/861; H01L 29/6609; H01L 29/04
USPC 257/49; 257/499; 438/439

(57) ABSTRACT

Electro-Static Discharge (ESD) protection using at least one ring-shape diode is disclosed. The ring-shape diode can be constructed from polysilicon, active region body on insulated substrate, or junction diode on silicon substrate. The diodes can have a first type of implant in an outer ring and a second type of implant in an inner ring to serve as two terminals of a diode coupled through contacts, vias, or metals. The two types of implant ring regions are separated with an isolation structure. The isolation can be LOCOS, STI, dummy gate, or silicide block layer (SBL). The ESD structure has at least a ring-shape diode with a first terminal coupled to an I/O pad and the second terminal coupled to a first supply voltage. The contours of the ring-shape diode can be circles, polygons, or other shapes. The ring-shape ESD structures can be multiple and be constructed in concentric manner.

### CROSS-REFERENCE TO RELATED APPLICATIONS

This application claims priority benefit of U.S. Provisional Patent Application No. 61/560,159, filed on Nov. 15, 2011 and entitled “Using Ring-Shape Polysilicon Diodes for Electro-Static Discharge (ESD) Protection,” which is hereby incorporated herein by reference

### BACKGROUND OF THE INVENTION

1. Field of the Invention

The present invention relates to Electro-Static Discharge (ESD) protection, i.e. using mechanism, device, circuit, apparatus, or any means to protection an integrated circuit from ESD damages.

2. Description of the Related Art

Human bodies may carry a lot of electrostatic charges. When an integrated circuit is touched by a human bodies during handling, a very high voltage (˜5 KV) and a high current (˜2 A) may be generated that can damage a delicate integrated circuit. The high voltage generated may breakdown MOS gate oxides, and the high power generated by high current may damage the metallurgical junctions. To protect an integrated circuit from ESD damages, the high voltage must be clamped, the high current must be limited, and the high heat generated from the high power consumption must be quickly dissipated to protect against temperature damage.

ESD protection becomes more important in today's semiconductor industry for several reasons. Firstly, as gate oxide of the MOS devices becomes thinner, it becomes more vulnerable to ESD damages due to aggressive scaling. Secondly, the threshold voltage of MOS devices in the core logic is lower from 0.7V to about 0.4V, and the breakdown voltage is lower from 5-7V to about 3-4V that can easily escape from the junction diodes' protection. Thirdly, high speed and high frequency circuits in an integrated circuit require very small input capacitance and yet good ESD protection. However, good ESD protection often requires large silicon area and high input capacitance. Therefore, the ESD protection issues deserve revisiting in today's nanometer devices.

FIG. 1 shows a prior art ESD protection device 10 that has an I/O pad 13 protected by two junction diodes 12 and 11. The P terminal of the diode 12 is coupled to VSS and the N terminal is coupled to the I/O pad 13. Similarly, the P terminal of the diode 11 is coupled to the I/O pad 13 and the N terminal is coupled to the VDD. The junction diodes 12 and 11 have a turn-on voltage of about 0.7V and a breakdown voltage of about 5V, for example. When a high positive voltage is applied to the I/O pad 13, the I/O pad 13 can be clamped to VDD+0.7 if the diode 11 is turned on and can be clamped to 5V, if the diode 12 is broken down. Similarly, when a high negative voltage is applied to the I/O pad 13, the I/O pad can be clamped to −0.7V if the diode 12 is turned on and can be clamped to VDD-5V if the diode 11 is broken down. Thus, the high voltage of ˜3 KV can be clamped to a very low voltage. The high heat generated by the high current during diode turn-on or breakdown can be quickly dissipated by guard rings surrounding the P terminal or N terminal of the diodes. The area of the diodes tends to be very large for better ESD immunity, but the large area is relatively costly.

FIG. 2 shows a conventional ESD protection device 20 for CMOS technologies that has an I/O pad 23 protected by two MOS devices connected as diodes 22 and 21. The P terminal of the diode 22 is coupled to VSS and the N terminal is coupled to the I/O pad 23. Similarly, the P terminal of the diode 21 is coupled to the I/O pad 23 and the N terminal is coupled to the VDD. The MOS diodes 22 and 21 have a turn-on voltage of about 0.6-0.7V and a breakdown voltage of about 4-5V depending on the MOS technologies. When a high positive voltage is applied to the I/O pad 23, the I/O pad 23 can be clamped to VDD+0.7, if the diode 21 is turned on and can be clamped to 5V if the diode 22 is broken down. Similarly, when a high negative voltage is applied to the I/O pad 23, the I/O pad can be clamped to −0.7V if the diode 22 is turned on and can be clamped to VDD-5V if the diode 21 is broken down. Thus, the high voltage of ˜3 KV can be clamped to a very low voltage. Other than the MOS connected as diodes to protect integrated circuits, the junction diodes in source/drain of the MOS devices 21 and 22 can also serve for protection. In other embodiments, the ESD protection can be based on source/drain of the MOS 21 and 22 while the gates of the MOS 21 and 22 are configured as output drivers.

A diode can be fabricated from polysilicon. FIG. 3(a) shows a cross section of a polysilicon diode. To form a polysilicon diode, a polysilicon is implanted by N+ at one end and P+ at the other end with a spacing Lc in between that has intrinsic doping level. The intrinsic doping level only means not intentionally doped with any dopants but can be slightly N type or P type due to out diffusion or contamination. A silicide block layer is applied to block silicide formation on the surface of the polysilicon to thus prevent a short circuit. The two ends of P+ and N+ in polysilicon are further brought out as P and N terminals of a diode through contacts, vias, or metals. As an example of a polysilicon diode, see Ming-Dou Ker et al., “Ultra High-Voltage Charge Pump Circuit in Low-Voltage Bulk CMOS Processes with Polysilicon Diodes,” IEEE Transaction of Circuit and System-II, Vol. 54, No. 1, January 2007, pp. 47-51.

FIG. 3(b) shows current verses voltage characteristics of a polysilicon diode, such as shown in FIG. 3(a). The current verses voltage curves show useful diode behavior such as a threshold voltage of about 0.6V and a leakage current of less than 1 nA. By varying the spacing Lc, the breakdown voltage and leakage current of the polysilicon diode can be adjusted accordingly.

Polysilicon diodes can be used for ESD protection, refer to Ming-Dou Ker et al, “High-Current Characterization of Polysilicon Diode for Electrostatic Discharge Protection in Sub-Quarter-Micron Complementary Metal Oxide Semiconductor Technology,” Jpn. J. Appl. Phys. Vol. 42, 2003, pp. 3377-3378. Polysilicon structures for ESD protection in the prior arts are about a one-piece rectangular structure, which has rooms for improvements. Thus, there is still a need to use an optimized polysilicon diode structure to achieve higher ESD voltage, lower input capacitance, smaller area, and lower heat generated in today's giga-Hertz circuits.

### SUMMARY

Embodiments of ESD protection using ring structures of diodes are disclosed. The diodes constructed from polysilicon or active region body on insulated substrate can be fabricated from standard bulk or SOI CMOS logic processes to achieve high ESD immunity, low input capacitance, small I/O size and low cost.

In one embodiment, the ESD protection can be constructed from diodes in ring structures that can be comparable to the I/O pad size and/or can be hidden underneath the pad partially or wholly. The diodes can be constructed from at least one polysilicon structure, insulated active region in SOI process, or junction diode in standard CMOS process. One ring-shape diode has the P terminal coupled to the pad and the N terminal coupled to VDD. The other ring-shape diode has the P terminal coupled to the VSS and the N terminal coupled to the pad. There can be a plurality of ring-shape structures and can be placed in concentric manner to maximize the ESD performance in small size. The contour of the diodes can be in circle, polygon or other shapes. In one embodiment, the P or N terminal of the ring-shape diodes is coupled to VDD, VSS, or pad through Active Areas (AAs) so that the heat generated can be quickly dissipated. Advantageously, the same diode structure can be used to create CMOS gates, sources, drains, or interconnects in standard CMOS logic processes. The input capacitance using ring-shape diodes can be smaller than that in the conventional junction diodes or MOS connected as diodes for the same ESD performance. Particularly, the turn-on voltage of polysilicon diodes is about 0.6V, smaller than 0.7V of junction diodes. The breakdown voltage of the polysilicon or active-region diodes can be easily changed by adjusting the spacing of the P+ and N+ implants or the doping concentration in the space between P+ and N+ implants. Thus, high performance and low cost ESD protection can be realized.

The invention can be implemented in numerous ways, including as a method, system, device, or apparatus (including graphical user interface and computer readable medium). Several embodiments of the invention are discussed below.

As a diode in an integrated circuit, one embodiment can, for example, include at least a ring-shape semiconductor body that having a first type of implant in the outer ring; a second type of implant in the inner ring; the two types of implant rings are separated by a spacing; and an isolation structure provided between the first and the second type of implant regions. The first and the second implant ring regions can be coupled through contacts and vias to serve as the first and the second terminals of a diode.

As an electronic system, one embodiment can, for example, include at least one integrated circuit having at least one ESD protection structure. The at least one ESD protection structure includes at least: at least one ring-shape diode having a first type of implant in an outer ring region, and a second type of implant in an inner ring region, the first type of implant serving as a first terminal for the at least one ring-shape diode, and the second type of implant serving as a second terminal for the at least one ring-shape diode. The first and second types of implants are separated with a space, and an isolation structure is provided between the first and the second implant regions. One of the first and second terminals of the at least one ring-shape diode can be coupled to an I/O pad while the other of the first and second terminals can be coupled to a supply voltage to protect circuits associated with the I/O pad from high voltage surges.

As a method for providing an Electro-Static Discharge (ESD) protection, one embodiment can, for include, include at least providing at least one ring-shape diode that includes at least (i) a first type of implant region in the outer portion of the ring to serve as a first terminal of the ring-shape diode; (ii) a second type of implant region in the inner portion of the ring to serve as a second terminal of the ring-shape diode; (iii) the first and second type of implant regions being separated with a space; (iv) an isolation structure provided between the first and the second type of implant regions; and (v) one of the first and second terminals of the at least one ring-shape diode being coupled to an I/O pad and the other of the first and second terminals being coupled to a supply voltage. The ring-shape diode can protect one or more circuits from a high voltage surge.

As an ESD device, one embodiment can, for example, include a plurality of ESD protection rings. At least one of the ESD protection rings can include at least one diode with P terminal coupled to the pad and the N terminal coupled to the VDD and at least another diode with P terminal coupled to the VSS and the N terminal coupled to the pad. The diode can be on a polysilicon or active-region body on an insulated substrate. The diode can also be a junction diode on a silicon substrate. Alternatively, the diode can have the P+ and N+ implant regions in the inner or outer part of a concentric ring. The P+ and N+ regions can be separated with a space, and a silicide block layer (SBL) can cover the space and overlap into both implant regions to construct P and N terminals of a diode. The P+ and N+ regions can be isolated by LOCOS (LOCal Oxidation), STI (Shallow Trench Isolation), dummy gate, or SBL in a junction diode on silicon substrate. In addition, the P and N terminals of the diodes coupled to VDD, VSS, or pad can be through contacts or vias to metals and/or through active areas to a thermally conductive substrate.

As an electronic system, one embodiment of the invention can, for example, include at least one Print Circuit Board (PCB), and at least one integrated circuit operatively connected to the PCB. The integrated circuit can include at least an I/O pad and at least one ESD protection structures. At least one of the ESD protection structures can include a ring-shape diode structure that has at least one diode with the P terminal coupled to the I/O pad and the N terminal coupled to the VDD and/or another diode with the P terminal coupled to the VSS and the N terminal coupled to the I/O pad. The diode can be on a polysilicon or active-region body on an insulated substrate. The diode can also be a junction diode on a silicon substrate. Alternatively, the P+ and N+ implant regions of the diode can be separated with a space (or isolation), such as LOCOS, STI, or dummy gate, and a silicide block layer can cover the space and overlap into both implant regions to construct P and N terminals of a diode, respectively. Also, the P or N terminal of the diodes can be coupled to VDD, VSS, or I/O pads through contacts or vias to metals, and/or through active areas to a thermally conductive substrate. There can be a plurality of ring-shape diode structures and placed in concentric manner. The contour of the diodes can be circle, polygon, or other shapes.

As a method for providing an ESD protection, one embodiment can, for example, include at least providing an ring-shape diode structure, where at least one of the ring-shape diode structures can include at least (i) a ring-shape diode with the P terminal coupled to an I/O pad and the N terminal coupled to a first supply voltage; and/or (ii) a ring-shape diode with the P terminal coupled to a second supply voltage and the N terminal coupled to the I/O pad. The diode can be a polysilicon or active-region body on an insulated substrate, or P/N junction on a silicon substrate. The P or N terminals of the diodes can be coupled to the first/second supply voltages or I/O pads through contacts or vias, to metal, and/or through active areas to a thermally conductive substrate. The embodiment of the invention can also include a plurality of concentric diode rings with the contour being circle, polygon, or other shapes.

Other aspects and advantages of the invention will become apparent from the following detailed description taken in conjunction with the accompanying drawings which illustrate, by way of example, the principles of the invention.

### BRIEF DESCRIPTION OF THE DRAWINGS

The present invention will be readily understood by the following detailed descriptions in conjunction with the accompanying drawings, wherein like reference numerals designate like structural elements, and in which:

FIG. 1 shows a prior art of ESD protection using diodes.

FIG. 2 shows a conventional ESD protection using MOS connected as diodes.

FIG. 3(a) shows a cross section of a polysilicon diode.

FIG. 3(b) shows current verses voltage characteristics of a polysilicon diode, such as shown in FIG. 3(a).

FIG. 4 shows a block diagram of an ESD protection structure using ring-shape diodes and an I/O pad according one embodiment.

FIG. 4(a) shows a cross section of a polysilicon diode, corresponding to the diodes in FIG. 4, according to one embodiment.

FIG. 4(b) shows a cross section of an active-region diode on an insulated substrate corresponding to the diodes in FIG. 4, according to another embodiment.

FIG. 4(c) shows a cross section of an active-region diode consisting of an N+ active region on a P substrate, corresponding to the diodes in FIG. 4, according to yet another embodiment.

FIG. 4(d) shows a cross section of an active-region diode consisting of P+ active region on an N well, corresponding to the diodes in FIG. 4, according to yet another embodiment.

FIG. 4(e) shows a cross section of an active-region diode consisting of an N+ active region on a P substrate with dummy gate isolation, corresponding to the diodes in FIG. 4, according to yet another embodiment.

FIG. 4(f) shows a cross section of an active-region diode consisting of P+ active region on an N well with dummy gate isolation, corresponding to the diodes in FIG. 4, according to yet another embodiment.

FIG. 5 shows a top view of a ring-shape polysilicon diode according to one embodiment.

FIG. 6(a) shows a top view of a ring-shape ESD protection structure according to one embodiment.

FIG. 6(b) shows a top view of a ring-shape ESD protection structure according to another embodiment.

FIG. 6(c) shows a top view of a ring-shape ESD protection structure according to yet another embodiment.

FIG. 7 shows a top view of a multiple ring-shape ESD protection structure according to one embodiment.

FIG. 8 shows an equivalent circuit of an ESD protection structure according to one embodiment.

FIG. 9(a) shows a Silicon-Controlled Rectifier (SCR) device on a semiconductor body according to one embodiment.

FIG. 9(b) shows an equivalent model of a SCR device according to one embodiment.

FIG. 9(c) shows a current versus voltage characteristic of an SCR device according to one embodiment.

FIG. 9(d) shows a ring-shape SCR device constructed on a semiconductor body according to one embodiment.

FIG. 10(a) shows a top view of a DIAC device constructed on a semiconductor body according to one embodiment.

FIG. 10(b) shows a current versus voltage characteristic of a DIAC device according to one embodiment.

FIG. 10(c) shows a ring-shape DIAC device constructed on a semiconductor body according to one embodiment.

FIG. 11(a) shows an equivalent model of a TRIAC that can be readily embodied on a semiconductor body according to one embodiment.

FIG. 11(b) shows a current versus voltage characteristic of a TRIAC device according to one embodiment.

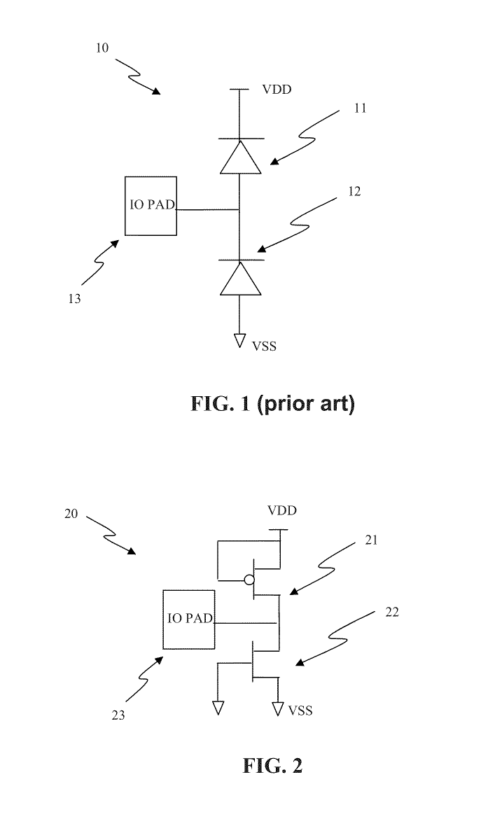

### DETAILED DESCRIPTION OF EMBODIMENTS OF THE INVENTION

Embodiments disclosed herein use an ESD structure with ring-shape diodes. The diodes can comprise P+ and N+ implants on a polysilicon or active region body on an insulated substrate with the P+ and N+ implants separated by a gap. The gap can be covered by a silicide block layer (SBL) and overlapping into both P+ and N+ areas. The diode can also be N+ active region on a P type substrate or P+ active region on an N well. The isolation between the P+ and N+ active regions can, for example, be LOCOS (LOCal Oxidation), STI (Shallow Trench Isolation), dummy gate, or SBL in standard CMOS processes. Since the P+ and N+ implants, active regions, and polysilicon are readily available in standard CMOS logic processes, these devices can be formed in an efficient and cost effective manner. There are no additional masks or process steps to save costs. The ESD protection device can also be included within an electronic system.

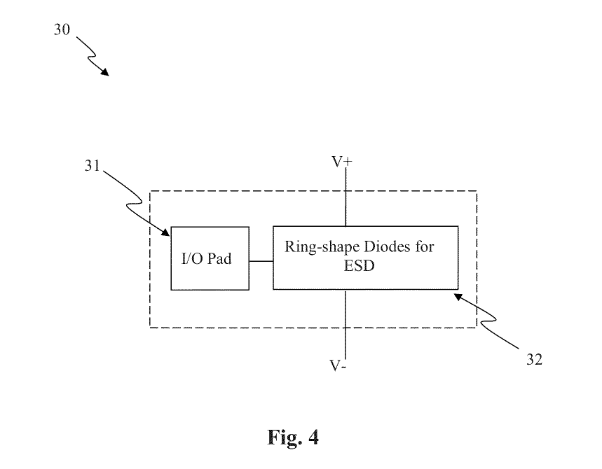

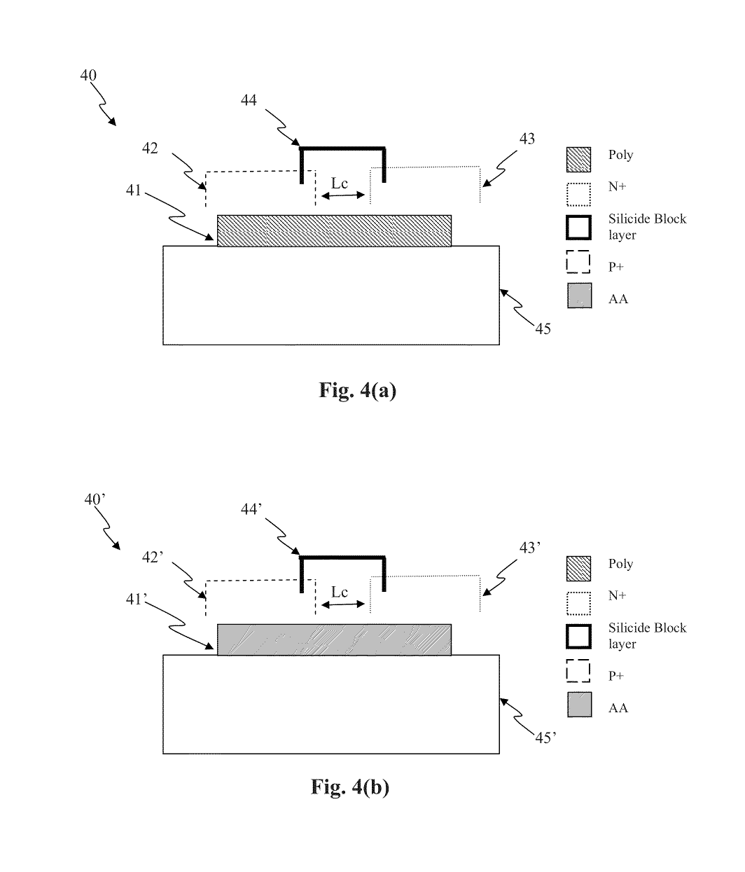

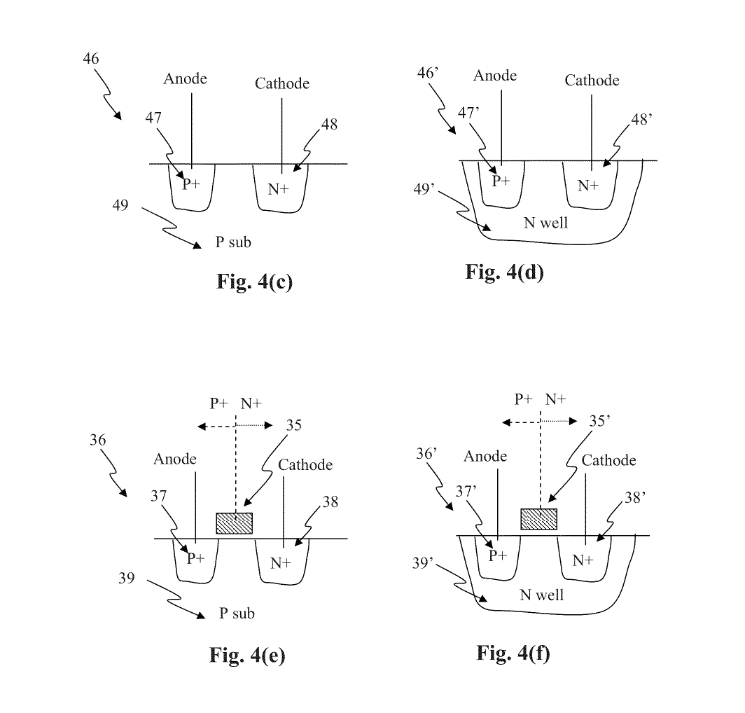

FIG. 4 shows a block diagram of an ESD protection device 30 using at least one ring-shape diodes according to one embodiment. In particular, the ESD protection device 30 includes an I/O pad 31 and at least one ring-shape diode 32. The I/O pad 31 can be coupled to an anode of the diode 32 with the cathode coupled to a high voltage V+, and/or coupled to a cathode of the diode 32 with the anode coupled to a low voltage V−. The couplings between anode(s) or cathode(s) of the diode(s) to external nodes can be through contacts, vias, or metals. In one implementation, the anode(s) and cathode(s) of the diode(s) can be coupled to a thermally conductive substrate through active areas, contacts, vias, or metals. By turning on or breaking down the diodes, a high ESD voltage on the I/O pad can be clamped to diodes' turning or breakdown voltages. Thus the internal devices of an integrated circuit coupled to an I/O pad can be protected from high ESD voltage damage.

FIG. 4(a) shows a cross section of a polysilicon diode 40, corresponding to the diodes in FIG. 4, according to one embodiment. The polysilicon diode structure 40 has a polysilicon body 41 on an insulated substrate 45 that has a P+ implant 42 in one end and an N+ implant 43 in the other end. The N+ 43 and P+ 42 are separated with a space Lc that can be used to adjust the breakdown voltage of the polysilicon diode. A silicide block layer (SBL) 44 covers the space Lc and overlaps into both P+ and N+ regions 42 and 43 to prevent a short due to silicide grown on the surface of the polysilicon 41. A portion of the N+ 43 and P+ 42 implant areas can be further coupled by contacts, vias, or metals (not shown in FIG. 4(a)) to external nodes as the cathode or anode of the polysilicon diode 40, respectively. The dopant concentration in the space Lc between P+ and N+ regions can be in the intrinsic level, namely, the dopants are not intentionally introduced but can be slightly P type or N type due to out diffusion or contamination. In another embodiment, the dopants in the space can be implanted slightly N or P type to control the resistance of the polysilicon diode 40.

FIG. 4(b) shows a cross section of an active-region diode 40′ on an insulated substrate 45′, corresponding to the diodes in FIG. 4, according to one embodiment. The insulated substrate 45′ is, for example, a SOI substrate. The active-region diode 40′ has an active-region body 41′ on the insulated substrate 45′ that has a P+ implant 42′ in one end and an N+ implant 43′ in the other end. The N+ 43′ and P+ 42′ are separated with a space Lc that can be used to adjust the breakdown voltage of the active-region diode 40′. A silicide block layer (SBL) 44′ covers the space Lc and overlaps into both P+ and N+ regions 42′ and 43′ to prevent a short due to silicide grown on the surface of the active region 41′. A portion of the N+ 43′ and P+ 42′ implant areas can be further coupled by contacts, vias, or metals (not shown in FIG. 4(b)) to external nodes as the cathode or anode of the active-region diode 40′, respectively. The dopant concentration in the space Lc between P+ and N+ regions can be in the intrinsic level, namely, the dopants are not intentionally introduced but can be slightly P type or N type due to out diffusion or contamination. In another embodiment, the dopants in the space can be implanted slightly N or P type to control the resistance of the active-region diode 40′.

FIG. 4(c) shows a cross section of an active-region diode 46 on a P type silicon substrate 49, corresponding to the diodes in FIG. 4, according to another embodiment. The active region diode 46 has an anode and a cathode that consist of a P+ active region 47 and an N+ active region 48 on a P type substrate 49. The anode and cathode can be further coupled through contact(s), via(s), or metal(s) (not shown in FIG. 4(c)) as the P and N terminals, respectively, of a diode. The isolation between the P+ 47 and N+ 48 can be LOCS or STI in other embodiment.

FIG. 4(d) shows a cross section of an active-region diode 46′ with a P+ active region 47′ and an N+ active region 48′ on an N well 49′, corresponding to the diodes in FIG. 4, according to another embodiment. The active region diode 46′ has an anode and a cathode that consist of a P+ active region 47′ and an N+ active region 48′ on an N well 49′. The anode and cathode can be further coupled through contact(s), via(s), or metal(s) (not shown in FIG. 4(d)) as the P and N terminals, respectively, of a diode. The isolation between the P+ 47′ and N+ 48′ can be LOCS or STI in other embodiment.

FIG. 4(e) shows a cross section of an active-region diode 36 on a P type silicon substrate 39, corresponding to the diodes in FIG. 4, according to another embodiment. The active region diode 36 has an anode and a cathode that consist of a P+ active region 37 and an N+ active region 38 on a P type substrate 39. The anode and cathode can be further coupled through contact(s), via(s), or metal(s) (not shown in FIG. 4(e)) as the P and N terminals, respectively, of a diode. The isolation between the anode and cathode can be a dummy gate 35 with part N+ and part P+ implants to create N+ and P+ active regions 38 and 37, respectively. The dummy gate 35 can be coupled to a fixed bias voltage during normal operations. In other embodiment, the dummy gate 35 can be replaced by a silicide block layer for isolation.

FIG. 4(f) shows a cross section of an active-region diode 36′ with a P+ active region 37′ and an N+ active region 38′ on an N well 39′, corresponding to the diodes in FIG. 4, according to another embodiment. The active region diode 36′ has an anode and a cathode that consist of a P+ active region 37′ and an N+ active region 38′ on an N well 39′. The anode and cathode can be further coupled through contact(s), via(s), or metal(s) (not shown in FIG. 4(f)) as the P and N terminals, respectively, of a diode. The isolation between the anode and cathode can be a dummy gate 35′ with part N+ and part P+ implants to create N+ and P+ active regions 38′ and 37′, respectively. The dummy gate 35′ can be coupled to a fixed bias voltage during normal operations. In other embodiment, the dummy gate 35 can be replaced by a silicide block layer for isolation.

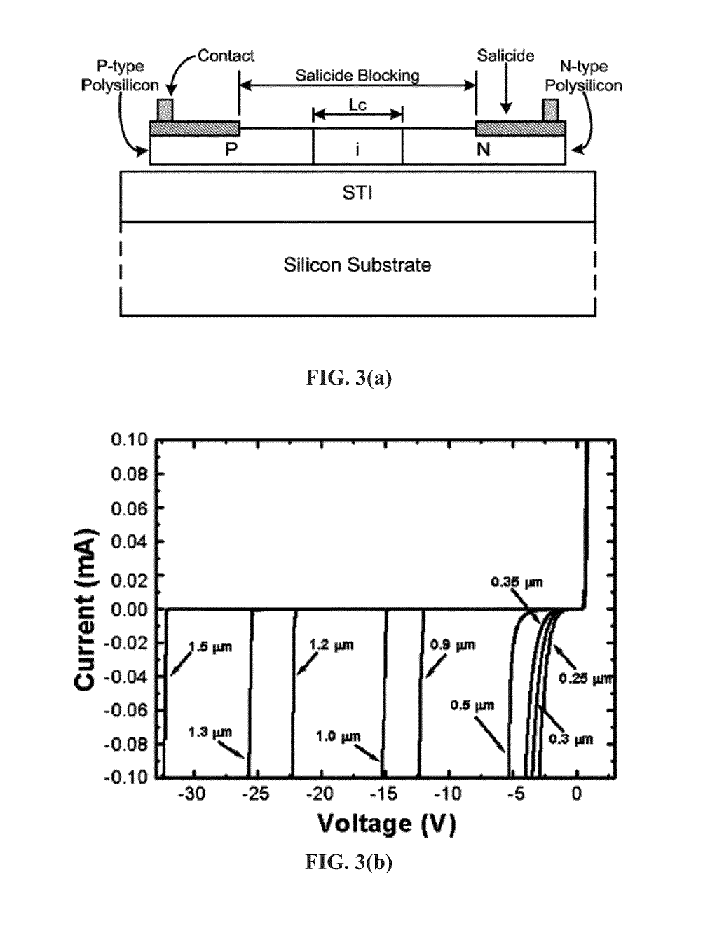

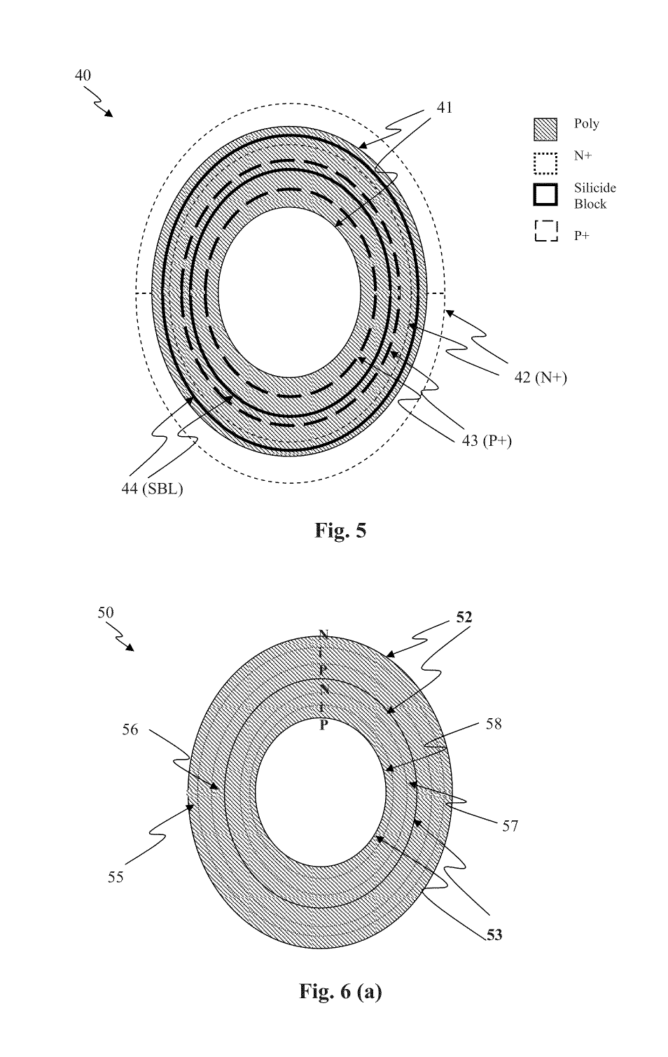

FIG. 5 shows a top view of a ring-shape polysilicon diode 40 according to one embodiment. The polysilicon diode structure 40 is similar to the cross section of a polysilicon diode shown in FIG. 3(a) except that the structure is a ring-shape. The circular structure allows uniform electrical field distribution, when a high voltage is applied, to prevent any sharp corners generating high electrical field and causing premature breakdown. The larger the radius of the circle, the lower the electrical field and the lower the current density generated by ESD voltage. The ring 42 is an N+ implant mask to allow heavy N type dopants being implanted into the polysilicon 40. The ring 43 is a P+ implant mask to allow heavy P type dopants to be implanted into the polysilicon 40. A portion of the N+ and P+ implant areas are further coupled by contacts, vias, or metals (not shown in FIG. 5) to external nodes, such as to the cathode or anode of the polysilicon diode 40, respectively. The P+ and N+ areas are preferably separated with a space Lc to adjust the breakdown voltage. The ring 44 is a silicide block layer (SBL) to prevent silicide from growing on the top of the polysilicon and shorting the P+ and N+ regions. The SBL 44 covers the gap between N+ and P+ and preferably overlaps into the P+ and N+ areas. The dopant concentration in the gap between P+ and N+ can be in the intrinsic level, namely, the dopants are not intentionally introduced but can be slightly P type or N type due to out diffusion or contamination. Alternatively, in another embodiment, the dopants in the gap can be implanted slightly N or P to control the resistance. The contour of the polysilicon diode 40 can be a circle, polygon, or other shape in yet another embodiment. The polysilicon diode 40 in FIG. 5 can be applied to an active-region diode built on SOI substrate, or a junction diode built on silicon substrate in other embodiments.

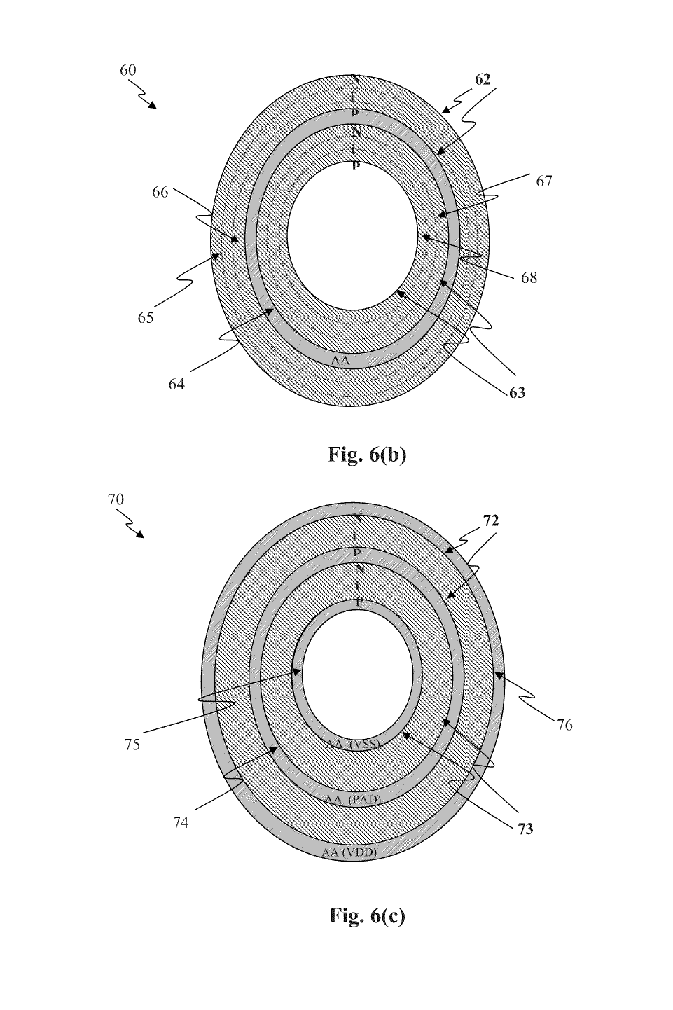

FIG. 6(a) shows a ring-shape ESD protection structure 50 according to one embodiment. The ESD protection structure 50 has a ring diode 52, as shown in FIG. 5, with an N+ 55 in an outer portion, a P+ 56 in an inner portion, and an intrinsic in a middle portion. The ESD protection structure 50 also has a ring diode 53, as shown in FIG. 5, with an N+ 57 in an outer portion, a P+ 58 in an inner portion, and an intrinsic in a middle portion. The N+ 55 of the diode ring 52 is coupled to VDD and the P+ 58 of the diode ring 53 is coupled to VSS. The P+ 56 of the diode 52 and the N+ 57 of the diode 53 are coupled to an I/O pad. For simplicity, the couplings through contacts, vias, or metals are not shown. The SBL layers in diodes 52 and 53 are also not shown.

FIG. 6(b) shows a ring-shape ESD protection structure 60 according to one embodiment. The ESD protection structure 60 has a ring diode 62, as shown in FIG. 5, with an N+ 65 in an outer portion, a P+ 66 in an inner portion, and an intrinsic in a middle portion. The ESD protection structure 60 also has a ring diode 63, as shown in FIG. 5, with an N+ 67 in an outer portion, a P+ 68 in an inner portion, and an intrinsic in a middle portion. The two ring diodes 62 and 63 are separated by an active area 64. The N+ 65 of the ring diode 62 can be coupled to VDD and the P+ 68 of the ring diode 63 can be coupled to VSS. The P+ 66 of the diode 62, the N+ 67 of the diode 63, and the active area 64 can be coupled to an I/O pad. For simplicity, the couplings through contacts, vias, or metals are not shown. The SBL layers in the ring diodes 62 and 63 are also not shown. The active area 64 creates a short thermal path to substrate for the I/O pad.

FIG. 6(c) shows a ring-shape ESD protection structure 70 according to one embodiment. The ESD protection structure 70 has a ring diode 72, as shown in FIG. 5, with an N+ in an outer region, a P+ in an inner region, and an intrinsic in a middle region. The ESD protection structure 70 also has a ring diode 73, as shown in FIG. 5, with an N+ in an outer region, a P+ in an inner region, and an intrinsic in a middle region. The two ring diodes 72 and 73 are separated by an active area 74 and surrounded by an active area 76 in the outer ring and an active area 75 in the inner ring. The N+ of the ring diode 72 can be coupled to VDD and the P+ of the ring diode 73 can be coupled to VSS. The P+ of the ring diode 72, the N+ of the ring diode 73, and the active area 74 can be coupled to an I/O pad. For simplicity, the couplings through contacts, vias, or metals are not shown. The SBL layers for ring diodes 72 and 73 are also not shown. The active areas 74, 75, and 76 create a short thermal path to substrate.

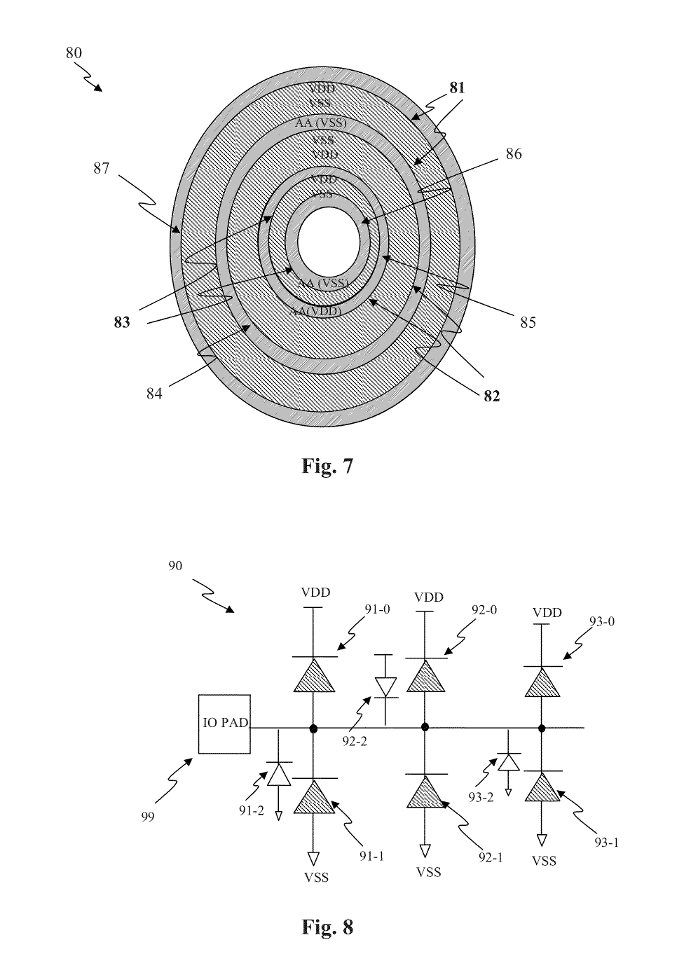

FIG. 7 shows a multiple ring-shape ESD protection structure 80 according to one embodiment. The ESD protection structure 80 has a ring-shape ESD structure 81, as shown in FIG. 6(a), 6(b), or 6(c), with an outer portion coupled to VDD and an inner coupled to VSS. The ESD protection structure 80 also has a ring-shape ESD structure 82, as shown in FIG. 6(a), 6(b), or 6(c), with an outer portion coupled to VSS and an inner portion coupled to VDD. The ESD protection structure 80 also has a ring-shape ESD structure 83, as shown in FIG. 6(a), 6(b), or 6(c), with an outer portion coupled to VDD and an inner portion coupled to VSS. The three ring-shape ESD structures 81, 82, and 83 are separated by an active area 84 and 85, and surrounded by an active area 87 in the outer portion and active area 86 in the inner portion. The active region 87 is coupled to VDD and the active region 86 is coupled to VSS. The active areas 84 and 85 are coupled to VSS and VDD, respectively. The I/O pad portions of the ring-shape ESD structures 81, 82, and 83 are coupled together to an I/O pad (not shown in FIG. 7). For simplicity, the couplings through contacts, vias, or metals are not shown. The N+, P+, and SBL layers of the ring-shape ESD structures 81, 82, and 83 are not shown either.

FIG. 8 shows an equivalent circuit 90 of a multiple ring-shape ESD structure as shown in FIG. 7 according to one embodiment. The equivalent circuit 90 has an I/O pad 99 coupled to a junction diode 91-2, polysilicon/active-region/junction diodes 91-0 and 91-1; coupled to a junction diode 92-2, polysilicon/active-region/junction diodes 92-0 and 92-1; coupled to a junction diode 93-2, polysilicon/active region/junction diodes 93-0 and 93-1, of ring-shape structures such as 81, 82, and 83 in the FIG. 7, respectively. For better performance, the width of the smaller inner rings can be increased slightly so that each ESD rings have the same ESD protection thresholds. To save area, the ring-shape ESD structure can be comparable to the size of the I/O pad and/or be hidden under the I/O pad partially or wholly.

Semiconductor body on an insulated substrate can be used to construct switch devices such as Silicon Controlled Rectifier (SCR), DIAC, or TRIAC. The semiconductor body can be a polysilicon or active region body on an insulated substrate.

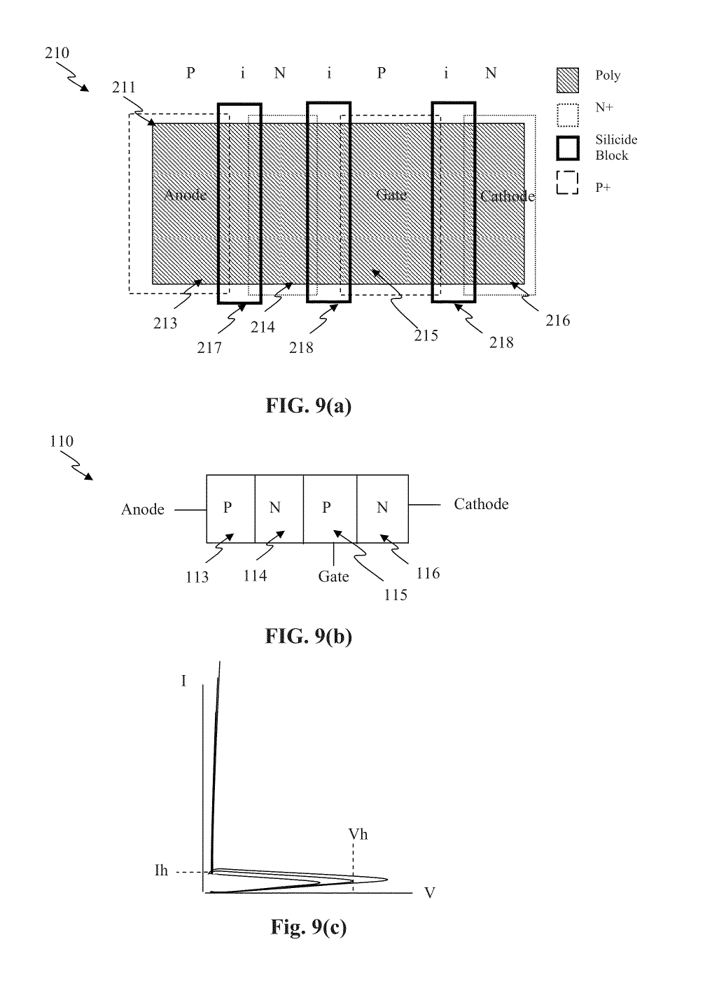

FIG. 9(a) shows a top view of a SCR 210 constructed on a semiconductor body 211 according to one embodiment. The semiconductor body 211 has implant regions 213, 214, 215, and 216 by P+, N+, P+, and N+ implants, respectively. The N+ implant regions 214 and 216 and P+ implant regions 213 and 215 are separated with a space. Silicide block layers 217, 218, and 219 cover the spaces and overlap into both implant regions to construct P/N junctions in the interface. The regions with P+ implant 213, N+ implant 216, and P+ implant 215 are coupled, respectively, as the anode, cathode, and gate of a SCR, through contacts, vias, or metals (not shown in FIG. 9(a)).

FIG. 9(b) shows an equivalent model of a SCR device 110 that has 4 layers of P+ and N+ regions, 113, 114, 115, and 116, alternatively, according to one embodiment. The external P+ and N+ regions 113 and 116 are brought out as the anode and cathode of an SCR. The internal P+ region 115 is brought out as the gate of an SCR.

FIG. 9(c) shows a current versus voltage characteristic of an SCR according to one embodiment. When a small voltage applied to an SCR, the SCR is not conductive. However, when the voltage is increased beyond Vh, the SCR suddenly becomes conductive and shows a low on-resistance state. Further, increasing the voltage makes the current higher and follows the on-resistance characteristics of the device. The Vh voltage can be controlled by a voltage applied to the gate as shown in the different curves in FIG. 9(c).

FIG. 9(d) shows a top view of a ring-shape of SCR 220 constructed on a semiconductor body 221 according to one embodiment. The semiconductor body 221 has ring-shape implant regions 223, 224, 225, and 226 by P+, N+, P+, and N+ implants, respectively. The ring-shape N+ implant regions 224 and 226 and ring-shape P+ implant regions 223 and 225 are separated by a space. Silicide block layers (not shown in FIG. 9(d)) cover the spaces and overlap into both implant regions to construct P/N junctions in the interface. The regions with P+ implant 223, N+ implant 226, and P+ implant 225 are coupled respectively as the anode, cathode, and gate of a SCR, respectively, through contacts, vias, or metals (not shown in FIG. 9(d)).

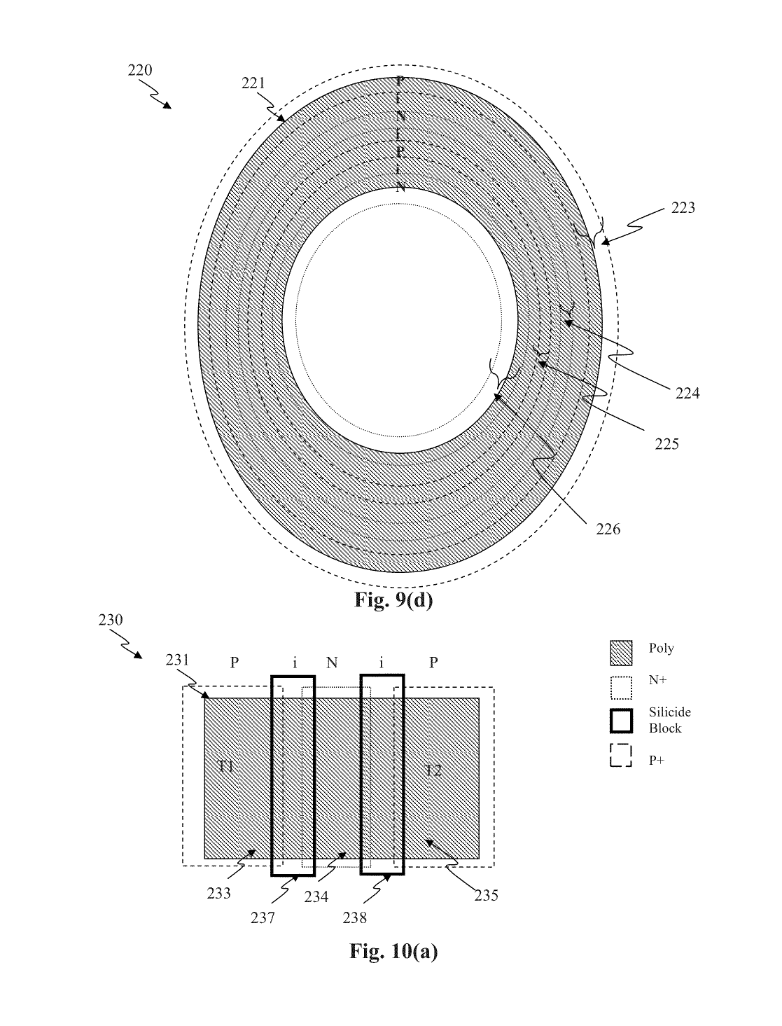

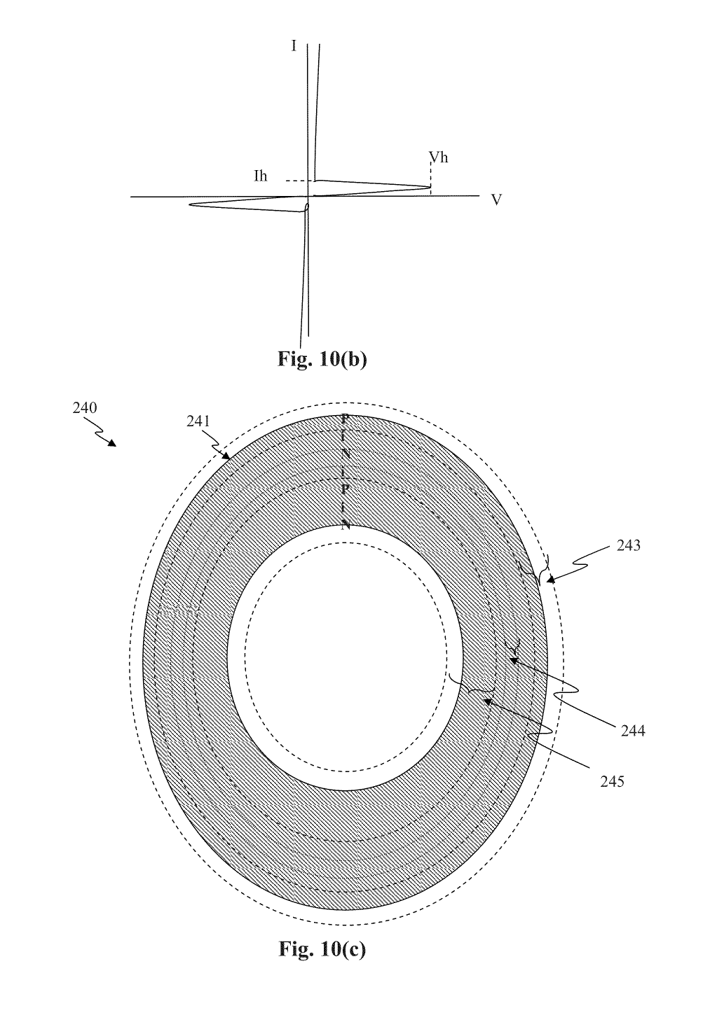

FIG. 10(a) shows a top view of a DIAC 230 constructed on a semiconductor body 231 according to one embodiment. The semiconductor body 231 has implant regions 233, 234, and 235, covered by P+, N+, and P+ implants, respectively. The N+ implant regions 234 and the P+ implant regions 233 and 235 are separated with a space. Silicide block layers 237 and 238 cover the spaces and overlap into both implant regions to construct P/N junctions in the interface. The regions with P+ implant 233 and P+ implant 235 are coupled respectively as the anode, cathode, T1 and T2 of a DIAC, through contacts, vias, or metals (not shown in FIG. 10(a)).

FIG. 10(b) shows a current versus voltage characteristic of the DIAC device 230 shown in FIG. 9(d), according to one embodiment. DIAC is a switch device similar to SCR, except that DIAC is a two-terminal device and does not have a gate terminal. When a voltage applied to the DIAC exceeds a critical voltage Vh, the DIAC becomes conductive. The DIAC shows the same characteristics with respect to a voltage applied in opposite polarity.

FIG. 10(c) shows a top view of a ring-shape of DIAC 240 constructed on a semiconductor body 241 according to one embodiment. The semiconductor body 241 has ring-shape implant regions 243, 244, and 245 by P+, N+, and P+ implants, respectively. The ring-shape N+ implant regions 244 and ring-shape P+ implant regions 243 and 245 are separated by spaces. Silicide block layers (not shown in FIG. 10(c)) cover the spaces and overlap into both implant regions to construct P/N junctions in the interface. The regions with P+ implant 243 and 245 are coupled respectively as the T1 and T2 of a DIAC, respectively, through contacts, vias, or metals (not shown in FIG. 10(c)).

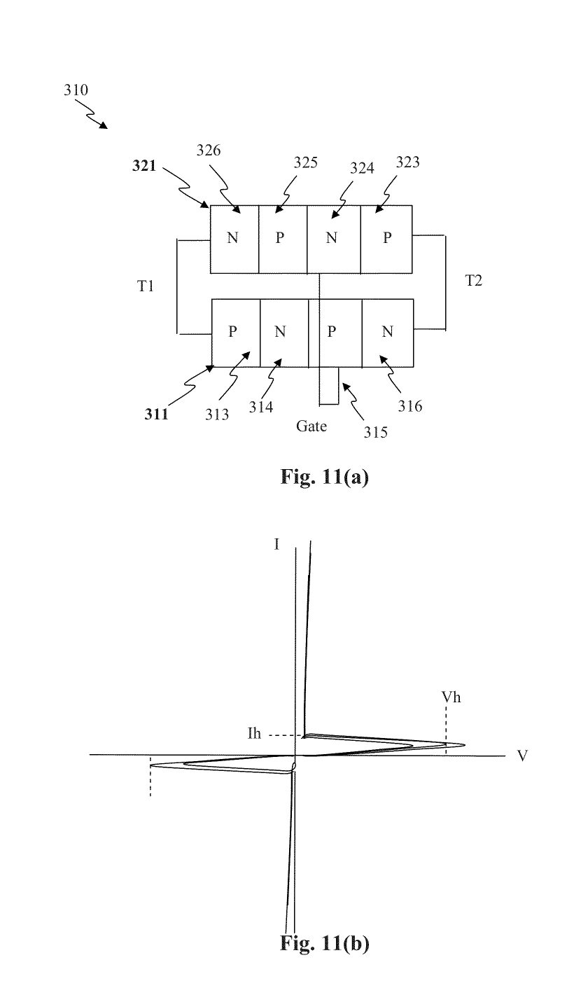

FIG. 11(a) shows an equivalent model of a TRIAC 310 that has two coupled SCR structures 311 and 321 according to one embodiment. The SCR 311 has a P-N-P-N structure of 313, 313, 315, and 316, respectively. The SCR 321 also has a P-N-P-N structure of 323, 324, 325, and 326, respectively. The anode 313 of SCR 311 is coupled to the cathode of SCR 321 as a terminal T1 of the TRIAC 310. The cathode 316 of SCR 311 is coupled to the anode of SCR 323 as a terminal T2 of the TRIAC 310. The internal P+ 315 of SCR 311 and the internal N+ 324 of SCR 321 are coupled as a gate of the TRIAC 310. The TRIAC structure in FIG. 11(a) can be readily embodied on a semiconductor body using SCR structures shown in FIG. 9(a) and FIG. 9(d).

FIG. 11(b) shows a current versus voltage characteristic of a TRIAC as shown in FIG. 310 according to one embodiment. The TRIAC characteristic is similar to the SCR except that the characteristic curves are symmetrical with respect to both voltage polarities.

Semiconductor body can be used to construct switch devices such as SCR, DIAC, or TRIAC based on P/N junctions built on the polysilicon or active region body on insulated substrate. The P/N junctions can be constructed from a gap between P+ and N+ implant regions and covered by a silicide block layer and overlapping into both implant regions. The dopant concentration in the gap can be not intentionally doped or slightly doped with N or P type to control the on-resistance. The DIAC, SCR, or TRIAC can be in any shape such as a circle, ring, rectangle, or polygon. The P+ and N+ implant regions in the above discussions are interchangeable. At least one of the P+ or N+ implant regions can be coupled to active areas and further coupled to a thermally conductive substrate. Those skilled in the art understand that the above discussions are for illustration purposes. There are many equivalent constructions and embodiments that can be applied and that are still within the scope of this invention.

The above discussions of various switch devices such as SCR, DIAC, or TRIAC based on a semiconductor body, or ESD structures based on ring-shape diodes are for illustration purposes. The semiconductor body can be on a conductive substrate through a dielectric, such as SiO2 on silicon substrate, or can be on a non-conductive substrate, such as mylar, plastic, glass, or paper, etc with a thin layer of semiconductor material coated on top. The substrate can be a film or a bulk. The ring-shape diodes for ESD structures can be a polysilicon, active region body on an insulated substrate, or junction diodes on a silicon substrate. For polysilicon or active-region diodes, the P+ and N+ implant regions can be separated with a gap. An SBL can cover the gap and overlap into the N+ and P+ regions. The width of the gap can be adjusted to change polysilicon or active region diodes' breakdown voltage. The doping concentration in the gap region can be changed to adjust the turn-on resistance. For junction diodes, the N+ and P+ active regions can be separated by LOCOS, STI, dummy gate, or SBL isolation. The N+ or P+ implant in the inner or outer ring is interchangeable. An active areas (AAs) can be introduced in any places to couple the diodes or switch devices to a thermally conductive substrate. The numbers of the supply voltages can be more than two, e.g., VDD and VSS. Those skilled in the art understand that there are many varieties and equivalent embodiments that are within the scope of this invention.

The invention can be implemented in a part or all of an integrated circuit in a Printed Circuit Board (PCB), or in a system. The ESD structures can comprise one or plural of ring-shape diode structures. Each ring-shape diode structure can comprise at least one ring-shape diodes with one terminal coupled to the I/O pad and the other terminal coupled to a supply voltage.

The above description and drawings are only to be considered illustrative of exemplary embodiments, which achieve the features and advantages of the present invention. Modifications and substitutions of specific process conditions and structures can be made without departing from the spirit and scope of the present invention.

The many features and advantages of the present invention are apparent from the written description and, thus, it is intended by the appended claims to cover all such features and advantages of the invention. Further, since numerous modifications and changes will readily occur to those skilled in the art, it is not desired to limit the invention to the exact construction and operation as illustrated and described. Hence, all suitable modifications and equivalents may be resorted to as falling within the scope of the invention.

What is claimed is:

1. A diode in an integrated circuit, comprising:
a ring-shape semiconductor body that having:
a first type of implant in the outer ring;
a second type of implant in the inner ring;
the two types of implant rings are separated by a spacing; and
an isolation structure provided between the first and the second type of implant regions; and
wherein the first and the second implant ring regions are coupled through contacts and vias to serve as the first and the second terminals of a diode.

2. A diode as recited in claim 1, wherein the semiconductor body is a polysilicon or active region body on an insulated substrate or a silicon substrate.

3. A diode as recited in claim 1, wherein the isolation structure is a silicide block layer, LOCOS (LOCal Oxidation), STI (Shallow Trench Isolation), or dummy gate.

4. An ESD protection structure provided in an integrated circuit, the ESD protection structure comprising:
an I/O pad; and
at least one ring-shape diode having:
a first type of implant in the outer ring region to serve as a first terminal of a diode;
a second type of implant in the inner ring region to serve as a second terminal of a diode;
the two types of implant regions being separated by a space;
an isolation structure between the first and the second implant regions; and
one of the terminals of the diode being coupled to an I/O pad while the other terminal being coupled to a supply voltage to protect the circuits associated with the I/O pad from high voltage surges.

5. An ESD protection structure recited in claim 4, wherein the semiconductor body is a polysilicon or active region body on an insulated substrate or a silicon substrate.

6. An ESD protection structure as recited in claim 4, wherein the isolation is a silicide block layer, LOCOS (LOCal Oxidation), STI (Shallow Trench Isolation), or dummy gate.

7. An ESD protection structure as recited in claim 4, wherein the contour of the diode is a circle or polygon.

8. An ESD protection structure as recited in claim 4, wherein the diode is comparable with the I/O pad size and/or is able to be hidden under the I/O pad partially or wholly.

9. An ESD protection structure as recited in claim 4, wherein at least one of the diode regions are coupled to adjacent active areas that are thermally coupled to a conductive substrate.

10. An ESD protection structure as recited in claim 4, wherein the ESD protection structure has a second diode, wherein the first diode has a first terminal coupled to the I/O pad and a second terminal coupled to a first supply voltage, and wherein the second diode has a second terminal coupled to the I/O pad and the first terminal coupled to a second supply voltage.

11. An electronic system, comprising:
at least one integrated circuit, the integrated circuit having at least one ESD protection structure,
the at least one ESD protection structure includes at least:
at least one ring-shape diode having a first type of implant in an outer ring region, and a second type of implant in an inner ring region, the first type of implant serving as a first terminal for the at least one ring-shape diode, the second type of implant serving as a second terminal for the at least one ring-shape diode,
wherein the first and second types of implants being separated with a space,
wherein an isolation structure is provided between the first and the second implant regions, and
wherein one of the first and second terminals of the at least one ring-shape diode is coupled to an I/O pad while the other of the first and second terminals being coupled to a supply voltage to protect circuits associated with the I/O pad from high voltage surges.

12. An electronic system as recited in claim 11, wherein the ring-shape diode comprises polysilicon or an active region body on an insulated substrate or a silicon substrate.

13. An electronic system as recited in claim 11, wherein the isolation structure is a silicide block layer, LOCOS (LOCal Oxidation), STI (Shallow Trench Isolation), or dummy gate.

14. An electronic system as recited in claim 11, wherein the contour of the at least one ring-shape diode is a circle or polygon.

15. An electronic system as recited in claim 11, wherein the at least one ring-shape diode is comparable to the I/O pad size and/or is hidden under the I/O pad partially or wholly.

16. An electronic system as recited in claim 11, wherein the implant ring regions of the at least one ring-shape diode are coupled to adjacent active areas that are thermally coupled to a conductive substrate.

17. An electronic system as recited in claim 11,
wherein the at least one ring-shape diode is a first ring-shape diode, and
wherein the ESD protection structure has a second ring-shape diode, wherein the first ring-shape diode has a first terminal coupled to the I/O pad and the second terminal coupled to a first supply voltage, and the second ring-shape diode has a second terminal coupled to the I/O pad and the first terminal coupled to a second supply voltage.

18. A method for providing an Electro-Static Discharge (ESD) protection, comprising:
providing at least one ring-shape diode that includes at least (i) a first type of implant region in the outer portion of the ring to serve as a first terminal of the ring-shape diode; (ii) a second type of implant region in the inner portion of the ring to serve as a second terminal of the ring-shape diode; (iii) the first and second type of implant regions being separated with a space; (iv) an isolation structure provided between the first and the second type of implant regions; and (v) one of the first and second terminals of the at least one ring-shape diode being coupled to an I/O pad and the other of the first and second terminals being coupled to a supply voltage,
wherein the ring-shape diode can protect one or more circuits from a high voltage surge.

19. A method as recited in claim 18, wherein the ring-shape diode is a polysilicon or an active region body on an insulated substrate or a silicon substrate.

20. A method as recited in claim 18, wherein the isolation structure is a silicide block layer, LOCOS (LOCal Oxidation), STI (Shallow Trench Isolation), or dummy gate.

21. A method as recited in claim 18, wherein the ring-shape diode has a contour, and wherein the contour of the diode is a circle or a polygon.

22. A method as recited in claim 18, wherein the method comprises:
providing a second ring-shape diode, wherein the first ring-shape diode has the first terminal coupled to an I/O pad and the second terminal coupled to a first supply voltage, and wherein the second ring-shape diode has a second terminal coupled to the I/O pad and the first terminal coupled to a second supply voltage.
